(19) United States
(12) Patent Application Publication
(10) Pub. No.: US 2024/0223139 A1
(43) Pub. Date: Jul. 4, 2024

(54) Radio Frequency Module

(71) Applicant: RADROCK (SHENZHEN) TECHNOLOGY CO., LTD, Shenzhen, Guangdong (CN)

(72) Inventors: Chuanqiu Lei, Shenzhen (CN); Yunlong Jiang, Shenzhen (CN); Kaiyao Yu, Shenzhen, (CN); Yongjian Lei, Shenzhen, (CN); Yuan Cao, Shenzhen (CN); Jianxing Ni, Shenzhen (CN)

(21) Appl. No.: 18/391,754

(22) Filed: Dec. 21, 2023

(30) Foreign Application Priority Data
Dec. 30, 2022 (CN) 202211741224.9
Mar. 31, 2023 (CN) 202310359595.9

(51) Int. Cl. H03F 3/24; H05K 1/02

(52) U.S. Cl. CPC H03F 3/245; H05K 1/0243; H03F 2200/09; H05K 2201/10166

(57) ABSTRACT

Disclosed is an RF module. The substrate includes a first layout area and a second layout area. The first RF chip is located in the first layout area, including a first power amplifier and a second power amplifier. The first switch chip is arranged in the first layout area and connected to the output ends of the first and second power amplifier. The second RF chip is arranged in second layout area, including a third power amplifier. The second switch chip is arranged in the second layout area and connected to the output end of the third power amplifier. The RF module shortens the transmission distance of RF signals between the first RF chip and first switch chip and between the second RF chip and second switch chip by arranging components in two areas separately, thus reducing the insertion loss and interference and improving the output quality of RF signals.

### CROSS REFERENCE TO RELATED APPLICATIONS

The present application claims the benefit of Chinese Patent Application No. 2022117412249, titled “RF module”, filed on Dec. 30, 2022 and Chinese Patent Application No. 2023103595959, titled “RF module”, filed on Mar. 31, 2023, the contents of which are incorporated herein by reference in their entirety.

### TECHNICAL FIELD

The application relates to the technical field of radio frequency (RF), and more specifically relates to an RF module.

### BACKGROUND

With the continuous development of RF technology, RF chip is becoming more and more integrated. When the RF chip is used, it is usually necessary to set the corresponding matching circuit on the substrate for processing the RF signal output by the RF chip, and set the corresponding switch chip on the substrate for controlling whether to output the processed RF signal.

However, for the positions of the RF chip and switch chip, if the layout and positions are unreasonable, it would not only increase the layout area of the substrate, but also affect the output effect of RF signals.

### SUMMARY

The embodiment of the application provides an RF module.

According to the first aspect of the application, an embodiment of the application provides an RF module, which includes a substrate, a first RF chip, a first switch chip, a second RF chip and a second switch chip. The substrate includes a first layout area and a second layout area, and the first layout area and the second layout area are located in different parts of the substrate respectively. The first RF chip is arranged in the first layout area and includes a first power amplifier and a second power amplifier, the first power amplifier is configured to receive a first input signal, the second power amplifier is configured to receive a second input signal, and a frequency of the first input signal is lower than that of the second input signal. The first switch chip is arranged in the first layout area and connected to an output end of the first power amplifier and an output end of the second power amplifier respectively. The second RF chip is arranged in the second layout area and includes a third power amplifier, the third power amplifier is configured to receive a third input signal, and a frequency of the third input signal is higher than that of the second input signal. The second switch chip is arranged in the second layout area and connected to an output end of the third power amplifier.

According to the second aspect of the application, an embodiment of the application further provides an RF module, which includes a substrate, a first RF chip, a second RF chip, a first switch chip and a second switch chip. The substrate is provided with a signal input port and a signal output port, the signal input port includes a first signal input port, a second signal input port and a third signal input port. A distance between the first signal input port and the second signal input port is smaller than that between the first signal input port and the third signal input port; the first signal input port is configured to input RF signals of a first frequency band, the second signal input port is configured to input RF signals of a second frequency band, and the third signal input port is configured to input RF signals of a third frequency band, and a frequency of the first frequency band is smaller than that of the second frequency band, and a frequency of the second frequency band is smaller than that of the third frequency band. The signal output port includes a first signal output port, a second signal output port and a third signal output port; a distance between the first signal output port and the second signal output port is smaller than that between the first signal output port and the third signal output port. The first RF chip is arranged on the substrate and connected with the first signal input port and the second signal input port. The second RF chip is arranged on the substrate and connected with the third signal input port. The first switch chip is arranged on the substrate and connected with the first RF chip, the first signal output port and the second signal output port. The second switch chip is arranged on the substrate and connected with the second RF chip and the third signal output port.

According to the third aspect of the application, an embodiment of the application further provides an RF module, which includes a substrate, an RF chip and a matching circuit. The substrate is provided with a power supply port and a signal output port. The RF chip is arranged on the substrate and connected to the power supply port. The matching circuit is arranged on the substrate and connected between the RF chip and the signal output port, and the matching circuit includes a first capacitor and a first balun. One end of the first capacitor is connected to the power supply port, and another end is grounded. The first balun is connected between the RF chip and the signal output port and surrounds a periphery of the first capacitor.

An embodiment of the application provides an RF module, which includes a substrate, a first RF chip, a first switch chip, a second RF chip and a second switch chip. The first RF chip and the first switch chip are located in the first layout area of the substrate, the second RF chip and the second switch chip are located in the second layout area of the substrate, and the first layout area and the second layout area are located in different parts of the substrate respectively. For example, the first RF chip and the first switch chip may be located in the lower area of the substrate, and the second RF chip and the second switch chip may be located in the upper area of the substrate. In this way, the RF module of the present application shortens the transmission distance of RF signals between the first RF chip and the first switch chip and between the second RF chip and the second switch chip by arranging components in two areas separately, thus reducing the insertion loss and interference of RF signals, so that the RF signals have better output quality when output from the RF module.

Further, the first RF chip may include a first power amplifier and a second power amplifier, and the second RF chip may include a third power amplifier, and the three power amplifiers can respectively amplify the received RF signals with different frequencies. For example, the first power amplifier can amplify low-frequency RF signals, the second power amplifier can amplify intermediate-frequency RF signals, and the third power amplifier can amplify high-frequency RF signals, which makes the application scenarios of the RF module more diverse.

An embodiment of the application further provides an RF module, which includes a substrate, a first RF chip, a first switch chip, a second RF chip and a second switch chip. The distance between the first signal input port and the second signal input port in this embodiment is smaller than the distance between the first signal input port and the third signal input port. Therefore, when the first RF chip and the second RF chip are arranged on the substrate, the first signal input port and the second signal input port can be closer to the first RF chip, the third signal input port can be closer to the second RF chip, which makes the layout of the trace between the first signal input port and the first RF chip, the trace between the second signal input port and the first RF chip and the trace between the third signal input port and the second RF chip more reasonable.

Further, the distance between the first signal output port and the second signal output port is smaller than that between the first signal output port and the third signal output port. Therefore, when the first switch chip and the second switch chip are arranged on the substrate, the first signal output port and the second signal output port can be closer to the first switch chip, the third signal output port can be closer to the second switch chip, so that the layout of the trace between the first signal output port and the first switch chip, the trace between the second signal output port and the first switch chip and the trace between the third signal output port and the second switch chip can be more reasonable.

An embodiment of the application further provides an RF module, including a substrate, an RF chip and a matching circuit. The substrate is provided with a power supply port and a signal output port, and the matching circuit includes a first capacitor and a first balun. The RF chip, first capacitor and first balun are all located on the substrate, and the first balun is connected between the RF chip and the signal output port and surrounds the periphery of the first capacitor. Therefore, in this application, the arrangement of the first capacitor in the middle of the first balun makes the overall structure of the matching circuit more compact and saves the layout area of the substrate.

Further, the RF chip in this application is connected to the power supply port, one end of the first capacitor is also connected to the power supply port, and another end is grounded. Therefore, when the power supply voltage is input from the power supply port to the RF chip, the first capacitor can play a role of decoupling, thereby suppressing the fluctuation of the power supply voltage and making the RF signal output by the RF chip more stable.

### BRIEF DESCRIPTION OF THE DRAWINGS

In order to explain the technical solution of the embodiments of this application more clearly, the drawings described in the description of the embodiments of this application will be briefly introduced below. Obviously, the drawings in the present application and their accompanying detailed description are directed to merely exemplary embodiments of the application. For those of ordinary skill in this field, other drawings may be obtained according to these drawings without any creative effort.

FIG. 1 is a structural schematic diagram of an RF module provided by the first embodiment of the present application.

FIG. 2 is a schematic cross-sectional view of the substrate in FIG. 1.

FIG. 3 is another structural schematic diagram of the RF module shown in FIG. 1.

FIG. 4 is a structural schematic diagram of the second matching circuit in FIG. 3.

FIG. 5 is another structural schematic diagram of the RF module shown in FIG. 1.

FIG. 6 is a structural schematic diagram of the RF module provided by the second embodiment of the present application.

FIG. 7 is a structural schematic diagram of the RF chip in FIG. 6.

FIG. 8 is another structural schematic diagram of the RF module shown in FIG. 6.

FIG. 9 is yet another structural schematic diagram of the RF module shown in FIG. 6.

FIG. 10 is another structural schematic diagram of the RF module shown in FIG. 6.

Reference signs in the drawings are as follows: RF module 100; Substrate 10; First RF chip 20; First switch chip 30; Second RF chip 40; Second switch chip 50; First layout area 120; Second layout area 140; First power amplifier 210; Second power amplifier 230; Third power amplifier 410; First metal layer 1100; Dielectric layer 1120; Second metal layer 1140; First signal input port 101; Second signal input port 102; Third signal input port 103; First signal output port 104; Second signal output port 105; Third signal output port 106; First power supply port 107; Second power supply port 108; Third power supply port 109; First power supply end 212; Second power supply end 214; Third power supply end 233; Fourth power supply end 234; Fifth power supply end 412; Sixth power supply end 414; First switch unit 320; Second switch unit 340; First matching circuit 60; Second matching circuit 70; Inductor 610; Balun 710; Capacitor 720; Primary-side trace part 7100; Secondary-side trace part 7120; First signal output end 231; Second signal output end 232; First secondary-side trace 7121; Second secondary-side trace 7126; Control chip 80; Third matching circuit 85; RF module 90; Substrate 910; RF chip 920; Matching circuit 930; Power supply port 9100; Signal output port 9120; First capacitor 940; First balun 950; First signal output end 9210; Second signal output end 9220; Signal input end 9230; First connection end 9240; Second connection end 9250; Power supply end 9260; First transistor 9201; Second transistor 9202; Third capacitor 9203; Fourth capacitor 9204; Second balun 9205; Third transistor 9206; Primary side 9207; Secondary side 9208; Primary-side trace part 9500; Secondary-side trace part 9520; First secondary-side trace 9521; Second secondary-side trace 9526; First jumper wire 9529; First primary-side trace 9501; Second primary-side trace 9506; Second capacitor 970; Wiring part 980; Second jumper wire 982; Third jumper wire 984; First wiring end 9800; Second wiring end 9820; First trace 9840.

### DETAILED DESCRIPTION OF PREFERRED EMBODIMENTS

In order to help those skilled in the art to better understand the solutions of the application, the technical solutions in the embodiments of the present application will be clearly and completely described below with reference to the drawings in the embodiments of this application. Obviously, the described embodiments are part of the embodiments of this application, but not all of them. Based on the embodiments in this application, all other embodiments obtained by those of ordinary skill in the art without creative effort belong to the protection scope of this application.

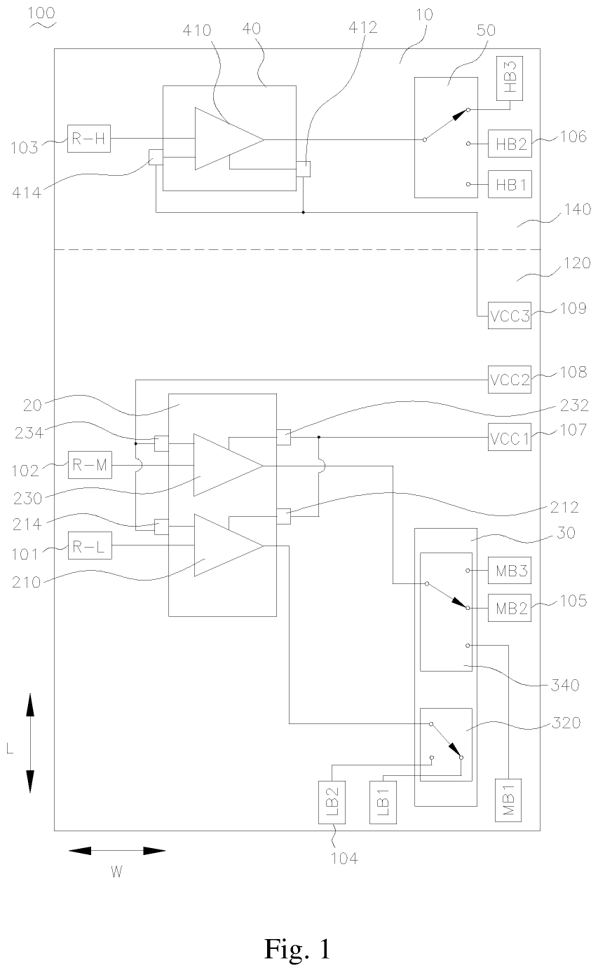

Referring to FIG. 1, the first embodiment of the present application provides an RF module 100, which is an element that integrates two or more discrete devices such as RF switch, low noise amplifier, filter, duplexer, power amplifier, etc. into an independent module, so as to improve the integration and hardware performance, and to miniaturize the volume. Specifically, the RF module 100 can be applied to 4G and 5G communication devices such as smart phones, tablet computers and smart watches. In this embodiment, the RF module 100 may include a substrate 10, a first RF chip 20, a first switch chip 30, a second RF chip 40 and a second switch chip 50. The substrate 10 includes a first layout area 120 and a second layout area 140, and the first layout area 120 and the second layout area 140 are located in different parts of the substrate 10. The first RF chip 20 is arranged in the first layout area 120 and includes a first power amplifier 210 and a second power amplifier 230; the first power amplifier 210 is configured to receive a first input signal, the second power amplifier 230 is configured to receive a second input signal, and the frequency of the first input signal is lower than that of the second input signal. The first switch chip 30 is arranged in the first layout area 120 and connected to an output of the first power amplifier 210 and an output of the second power amplifier 230, respectively. The second RF chip 40 is arranged in the second layout area 140 and includes a third power amplifier 410; the third power amplifier 410 is configured to receive a third input signal, and the frequency of the third input signal is higher than that of the second input signal. The second switch chip 50 is arranged in the second layout area 140 and connected to an output end of the third power amplifier 410.

In this embodiment, the first RF chip 20 and the first switch chip 30 are arranged in the first layout area 120 of the substrate 10, the second RF chip 40 and the second switch chip 50 are arranged in the second layout area 140 of the substrate 10, and the first layout area 120 and the second layout area 140 are located in different parts of the substrate 10. For example, the first RF chip 20 and the first switch chip 30 may be located in the lower area of the substrate 10, and the second RF chip 40 and the second switch chip 50 may be located in the upper area of the substrate 10. Therefore, the RF module 100 of the present application shortens the transmission distance of RF signals between the first RF chip 20 and the first switch chip 30 and between the second RF chip 40 and the second switch chip 50 by arranging components in two areas separately, thus reducing the insertion loss, so that the RF signals have better output quality when output from the RF module 100.

Further, the first RF chip 20 may include a first power amplifier 210 and a second power amplifier 230, and the second RF chip 40 may include a third power amplifier 410, and the three power amplifiers may each amplify the received RF signals with different frequencies. For example, the first power amplifier 210 can amplify low-frequency RF signals, the second power amplifier 230 can amplify intermediate-frequency RF signals, and the third power amplifier 410 can amplify high-frequency RF signals, which makes the application scenarios of the RF module 100 more diverse.

Each module included in the RF module 100 of the first embodiment is described below.

The substrate 10 has a roughly rectangular shape, and is used to fixedly support components in the RF module 100 (for example, first RF chip 20, first switch chip 30, second RF chip 40, second switch chip 50, etc.). Specifically, the substrate 10 may be a copper-clad laminate, and a circuit can be printed on the surface of the substrate 10 by processing the copper-clad laminate with holes, electroless copper plating, copper electroplating and etching.

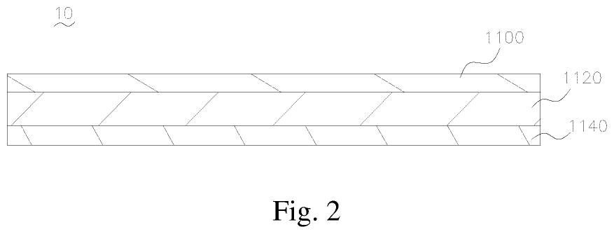

In some possible embodiments, the substrate 10 may adopt the structure of double metal layer. Specifically, referring to FIG. 2, the substrate 10 may include a first metal layer 1100, a dielectric layer 1120 and a second metal layer 1140; the first metal layer 1100, the dielectric layer 1120, and the second metal layer 1140 are sequentially stacked in the thickness direction of the substrate 10, i.e., the first metal layer 1100 and the second metal layer 1140 are arranged on opposite sides of the dielectric layer 1120 at intervals. Specifically, the first metal layer 1100 may be used for trace layout (e.g., equivalent traces of inductor and balun) and fixedly supporting components in the RF module 100 (e.g., first RF chip 20, first switch chip 30, etc.). The second metal layer 1140 may be used for trace layout. Illustratively, the second metal layer 1140 may be used for signal port arrangement (e.g., signal input port, signal output port, etc.) and be grounded to a metal plate. Specifically, the trace located in the first metal layer 1100 and the trace located in the second metal layer 1140 may be connected through the conductive via provided in the dielectric layer 1120, so that redundant jumper wire can be eliminated, and the components in the RF module 100 can be more flexible in layout.

In this embodiment, the substrate 10 includes a first layout area 120 and a second layout area 140, which are located in different parts of the substrate 10. The first layout area 120 and the second layout area 140 may be arranged side by side on the substrate 10. For example, in FIG. 1, the first layout area 120 and the second layout area 140 are arranged side by side in the first direction L of the substrate 10; the first layout area 120 may be located in the lower area of the substrate 10, and the second layout area 140 may be located in the upper area of the substrate 10. Specifically, the first direction L may be the length direction of the substrate 10.

In other possible embodiments, the first layout area 120 and the second layout area 140 may be arranged side by side in the second direction W of the substrate 10, and the second direction W intersects with the first direction L. For example, the first layout area 120 may be located approximately in the left area of the substrate 10, and the second layout area 140 may be located approximately in the right area of the substrate 10. Specifically, the second direction W may be the width direction of the substrate 10, and the second direction W is perpendicular to the first direction L.

In this embodiment, the first layout area 120 and the second layout area 140 may be two areas adjacent to each other, so that the elements arranged on the substrate 10 can be more compact. For example, in FIG. 1, the first layout area 120 and the second layout area 140 are adjacent to each other. In other possible embodiments, the first layout area 120 and the second layout area 140 may also be two non-adjacent areas. Illustratively, the substrate 10 may further include a third layout area (not shown in the figure), which is arranged between the first layout area 120 and the second layout area 140. For example, the first layout area 120, the third layout area and the second layout area 140 may be arranged side by side in the first direction L. Specifically, this embodiment does not specifically limit the specific division mode of the layout area on the substrate 10.

In this embodiment, multiple chips or circuits positioned in the same layout area are used to transmit at least one set of RF signals, while multiple chips or circuits positioned in different layout areas transmit different RF signals. Illustratively, the first RF chip 20 and the first switch chip 30 arranged in the first layout area 120 can be used for transmitting medium and low frequency signals, and the second RF chip 40 and the second switch chip 50 arranged in the second layout area 140 can be used for transmitting high frequency signals. Therefore, the RF module 100 of the present application shortens the transmission distance of RF signals between the first RF chip 20 and the first switch chip 30 and between the second RF chip 40 and the second switch chip 50 by arranging components in two areas separately, thus reducing the insertion loss, so that the RF signals have better output quality when output from the RF module 100.

In this embodiment, the substrate 10 may also be provided with a first signal input port 101, a second signal input port 102 and a third signal input port 103. The first signal input port 101, the second signal input port 102, and the third signal input port 103 are arranged at the edge of the substrate 10, and each of them is used for receiving the RF signals input from the outside into the RF module 100. In FIG. 1, the first signal input port 101 and the second signal input port 102 are arranged in the first layout area 120, and the third signal input port 103 is arranged in the second layout area 140. The first signal input port 101, the second signal input port 102, and the third signal input port 103 are roughly arranged on the side of the first RF chip 20 away from the first switch chip 30, i.e., at the left edge of the substrate 10 in FIG. 1, and are sequentially arranged at intervals in the first direction L. And, the first direction L may be the length direction of the substrate 10. In some possible embodiments, the substrate 10 adopts the structure of double metal layer. The first signal input port 101, second signal input port 102 and third signal input port 103 may be arranged on the second metal layer 1140 of the substrate 10, so that the first metal layer 1100 has more sufficient layout space.

Specifically, the first signal input port 101 can be used to receive the first input signal, the second signal input port 102 can be used to receive the second input signal, and the third signal input port 103 can be used to receive the third input signal. The frequency of the first input signal is lower than that of the second input signal, and the frequency of the third input signal is higher than that of the second input signal. Illustratively, the first input signal may be a low frequency (e.g., less than 300 kHz) RF signal, the second input signal may be a medium frequency (e.g., greater than 3 MHz and less than 30 MHz) RF signal, and the third input signal may be a high frequency (e.g., greater than 300 MHZ) RF signal. Therefore, the RF module 100 in this embodiment can process a plurality of RF signals with different frequencies, so that the application scenarios of the RF module 100 are more diverse.

In this embodiment, the substrate 10 may also be provided with a first signal output port 104, a second signal output port 105 and a third signal output port 106. The first signal output port 104, second signal output port 105 and third signal output port 106 are arranged at the edge of the substrate 10, and are used for outputting RF signals with different frequencies respectively.

Specifically, the number of the first signal output ports 104 may be plural. For example, in some possible embodiments, the number of the first signal output ports 104 is five, and a plurality of the first signal output ports 104 are arranged in the first layout area 120 and are sequentially arranged at intervals in the second direction W. The second direction W may be the width direction of the substrate 10, and the first direction L and the second direction W intersect and are roughly perpendicular. In FIG. 1, a plurality of first signal output port 104 are roughly arranged at the side of the first RF chip 20 away from the second RF chip 40, i.e., at the lower edge of the substrate 10 in FIG. 1, which can be used to output low-frequency signals processed by the RF module 100.

The number of the second signal output ports 105 may be plural. For example, in some possible embodiments, the number of the second signal output ports 105 is five, and a plurality of the second signal output ports 105 are arranged in the first layout area 120 and are sequentially arranged at intervals in the first direction L. In FIG. 1, a plurality of second signal output port 105 are roughly arranged at the side of the first switch chip 30 away from the first RF chip 20, i.e., at the lower right edge of the substrate 10 in FIG. 1, which can be used to output intermediate frequency signals processed by the RF module 100.

The number of the third signal output ports 106 may be plural. For example, in some possible embodiments, the number of the third signal output ports 106 is six, and a plurality of the third signal output ports 106 are arranged in the second layout area 140 and are sequentially arranged at intervals in the first direction L. In FIG. 1, a plurality of third signal output ports 106 are roughly arranged at the side of the second switch chip 50 away from the second RF chip 40, i.e., at the upper right edge of the substrate 10 in FIG. 1, which can be used to output high-frequency signals processed by the RF module 100.

In some possible embodiments, the substrate 10 adopts the structure of double metal layer. The plurality of first signal output ports 104, the plurality of second signal output ports 105 and the plurality of third signal output ports 106 can be arranged on the second metal layer 1140 of the substrate 10, so that the first metal layer 1100 has more sufficient layout space.

In this embodiment, the substrate 10 may also be provided with a plurality of control ports for inputting control signals sent from the outside. The plurality of control ports may be arranged at the edge of the substrate 10 to facilitate the input of control signals. For example, the plurality of control ports may be roughly arranged at the left edge of the substrate 10; and the plurality of control ports, the first signal input port 101, second signal input port 102 and third signal input port 103 are sequentially arranged at intervals in the first direction L. Illustratively, the plurality of control ports may include a control port SDATA, a control port SCLK and a control port VIO. The control port SDATA is used to receive control instructions, the control port SCLK is used to receive control clock signals, and the control port VIO is used to receive digital input/output interface power.

In this embodiment, the substrate 10 is provided with a first power supply port 107, a second power supply port 108 and a third power supply port 109. Each of the first power supply port 107, second power supply port 108 and third power supply port 109 is used for connecting an external power supply. The external power supply supplies power to the components on the substrate 10 through the first power supply port 107, second power supply port 108 and third power supply port 109. And, the external power supply can be used to provide a supply voltage (Volt Current Condenser, VCC), which may be 3.3V, 5V, 12V, etc., and it is not specifically limited in this embodiment. In some possible embodiments, the substrate 10 adopts the structure of double metal layer. The plurality of control ports and the first power supply port 107, second power supply port 108 and third power supply port 109 can be arranged on the second metal layer 1140 of the substrate 10, so that the first metal layer 1100 has more sufficient layout space.

The first RF chip 20 is arranged on the substrate 10 and located in the first layout area 120 of the substrate 10, and is used for power amplification of the input RF signal. Specifically, the first RF chip 20 may be attached to the substrate 10, inserted into the substrate 10, or welded to the substrate 10 by welding (for example, soldering).

In this embodiment, the first RF chip 20 may include a first power amplifier 210 and a second power amplifier 230, and the input end of the first power amplifier 210 is connected to the first signal input port 101, i.e., the first power amplifier 210 is configured to receive the first input signal input from the first signal input port 101. The input end of the second power amplifier 230 is connected to the second signal input port 102, i.e., the second power amplifier 230 is configured to receive the second input signal.

Specifically, the first power amplifier 210 and the second power amplifier 230 may be single-ended amplifier circuits or differential amplifier circuits. In some possible embodiments, the first power amplifier 210 is a single-ended amplifier circuit and the second power amplifier 230 is a differential amplifier circuit. Because the first input signal received by the first power amplifier 210 is a low-frequency signal, the low-frequency signal can be amplified by using a single-ended amplifier circuit structure, thereby saving the cost of hardware of the first power amplifier 210.

In this embodiment, both the first power amplifier 210 and the second power amplifier 230 are two-stage amplifier circuits. The first power amplifier 210 may include a first power supply end 212 and a second power supply end 214, and the second power amplifier 230 may include a third power supply end 233 and a fourth power supply end 234. The first power supply end 212 and the third power supply end 233 are connected to the first power supply port 107, and the second power supply end 214 and the fourth power supply end 234 are connected to the second power supply port 108. In this way, the first power supply port 107 and the second power supply port 108 in this embodiment supply power to the first power supply end 212 and the second power supply end 214 in the first power amplifier 210, respectively. Thereby meeting different power supply voltages required by the first power supply end 212 and the second power supply end 214, and enabling the first power amplifier 210 to work more stably. In addition, the first power supply port 107 and second power supply port 108 also supply power to the third power supply end 233 and fourth power supply end 234 of the second power amplifier 230, respectively. Thereby meeting the different power supply voltages required by the third power supply end 233 and fourth power supply end 234, and enabling the second power amplifier 230 to work more stably.

The first switch chip 30 is arranged on the substrate 10 and located in the first layout area 120. The first switch chip 30 is connected to the output end of the first power amplifier 210 and the output end of the second power amplifier 230 respectively, and is used for controlling the output state of the RF signal amplified by the first power amplifier 210 and the second power amplifier 230. Specifically, the first switch chip 30 may be attached to the substrate 10, inserted into the substrate 10, or welded to the substrate 10 by welding (for example, soldering).

In this embodiment, the first switch chip 30 may include a first switch unit 320 and a second switch unit 340. The first switch unit 320 is connected to the output end of the first power amplifier 210, and is used for controlling the output state of the RF signal processed by the first power amplifier 210. For example, when the first switch unit 320 is on, the RF signal processed by the first power amplifier 210 can be smoothly output from the RF module 100. On the contrary, when the first switch unit 320 is off, the RF signal processed by the first power amplifier 210 cannot be output from the RF module 100. The second switch unit 340 is connected to the output end of the second power amplifier 230, and is used for controlling the output state of the RF signal processed by the second power amplifier 230. For the specific working process of the second switch unit 340, please refer to the related description of the first switch unit 320, which is not repeated here.

Specifically, the first switch unit 320 is connected to the first signal output port 104, the distance between the first signal output port 104 and the first switch unit 320 is smaller than that between the first signal output port 104 and the second switch unit 340. Thereby shortening the signal transmission distance between the first signal output port 104 and the first switch unit 320, and reducing the signal insertion loss of the RF signal output from the first switch unit 320. Similarly, the second switch unit 340 is connected to the second signal output port 105, the distance between the second signal output port 105 and the second switch unit 340 is smaller than that between the second signal output port 105 and the first switch unit 320. Thereby shortening the signal transmission distance between the second signal output port 105 and the second switch unit 340, and reducing the signal insertion loss of the RF signal output from the second switch unit 340.

In this embodiment, the first RF chip 20 and the first switch chip 30 are arranged at intervals in the second direction W approximately. The first signal input port 101 and the second signal input port 102 are located on the side of the first RF chip 20 away from the first switch chip 30, the first signal output port 104 is located on the side of the first switch unit 320 away from the first RF chip 20 in the first direction L, and the second signal output port 105 is located on the side of the second switch unit 340 away from the first RF chip 20 in the second direction W. Specifically, the first signal input port 101, first RF chip 20, and first switch chip 30 are arranged in sequence in the second direction W approximately, the second signal input port 102, first RF chip 20 and first switch chip 30 are arranged in sequence in the second direction W, the first signal output port 104, first switch chip 30, and first RF chip 20 are arranged in sequence in the first direction L approximately, and the second signal output port 105, first switch chip 30, and first RF chip 20 are arranged in sequence in the second direction W approximately. With the above arrangement, the RF module 100 can shorten the signal transmission paths among the first signal input port 101, first power amplifier 210, first switch unit 320 and first signal output port 104, and shorten the signal transmission path among the second signal input port 102, second power amplifier 230, second switch unit 340 and second signal output port 105, thereby reducing the signal insertion loss. It also makes the arrangement among the first signal input port 101, second signal input port 102, first RF chip 20, first switch chip 30, first signal output port 104 and second signal output port 105 more compact and reasonable.

The second RF chip 40 is arranged on the substrate 10 and located in the second layout area 140 of the substrate 10, and is used for power amplification of the input RF signal. Specifically, the second RF chip 40 may be attached to the substrate 10, inserted into the substrate 10, or welded to the substrate 10 by welding (for example, soldering).

In this embodiment, the second RF chip 40 may include a third power amplifier 410, and the input end of the third power amplifier 410 is connected to the third signal input port 103, i.e., the third power amplifier 410 is configured to receive the third input signal input from the third signal input port 103.

Specifically, in FIG. 1, the distance between the first signal input port 101 and second signal input port 102 is smaller than the distance between the second signal input port 102 and third signal input port 103. Therefore, when the first RF chip 20 and the second RF chip 40 are arranged on the substrate 10, the first signal input port 101 and second signal input port 102 can be closer to the first RF chip 20, the third signal input port 103 can be closer to the second RF chip 40, so that the layout of the trace between the first signal input port 101 and first RF chip 20, the trace between the second signal input port 102 and first RF chip 20, and the trace between the third signal input port 103 and second RF chip 40 can be more reasonable. It should be noted that “the distance between the first signal input port 101 and second signal input port 102” can be understood as the straight-line distance between the geometric center of the first signal input port 101 and the geometric center of the second signal input port 102. For example, when the first signal input port 101 is rectangular, its geometric center is the center of the rectangle; when the first signal input port 101 is circular, its geometric center is the circle center.

In this embodiment, the third power amplifier 410 is a two-stage amplifier circuit, and the third power amplifier 410 includes a fifth power supply end 412 and a sixth power supply end 414. The substrate 10 is further provided with a third power supply port 109, which is connected to the fifth power supply end 412 and the sixth power supply end 414. In this way, the third power supply port 109 in this embodiment is used to supply power to the second RF chip 40, and the first power supply port 107 and second power supply port 108 are used to supply power to the first RF chip 20, thereby realizing the separation of power supply. That is, the first RF chip 20 and second RF chip 40 can work independently, in the event that at least one of the first power supply port 107 and second power supply port 108 fails, the regular operation of the second RF chip 40 will not be affected; and in the event that the third power supply port 109 fails, the regular operation of the first RF chip 20 will not be affected.

The second switch chip 50 is arranged on the substrate 10 and located in the second layout area 140. The second switch chip 50 is connected to the output end of the third power amplifier 410, and is used for controlling the output state of the RF signal amplified by the third power amplifier 410. For example, when the second switch chip 50 is on, the RF signal processed by the third power amplifier 410 can be smoothly output from the RF module 100. On the contrary, when the second switch chip 50 is off, the RF signal processed by the third power amplifier 410 cannot be output from the RF module 100. Specifically, the second switch chip 50 may be attached to the substrate 10, inserted into the substrate 10, or welded to the substrate 10 by welding (for example, soldering).

Specifically, the second switch chip 50 is connected to the third signal output port 106, and the distance between the first signal output port 104 and the second signal output port 105 is smaller than that between the first signal output port 104 and the third signal output port 106. Therefore, when the first switch chip 30 and second switch chip 50 are arranged on the substrate 10, the first signal output port 104 and second signal output port 105 can be closer to the first switch chip 30, the third signal output port 106 can be closer to the second switch chip 50, so that the layout of the trace between the first signal output port 104 and first switch chip 30, the trace between the second signal output port 105 and first switch chip 30, and the trace between the third signal output port 106 and second switch chip 50 can be more reasonable. It should be noted that “the distance between the first signal output port 104 and the second signal output port 105” can be understood as the straight-line distance between the geometric center of the first signal output port 104 and the geometric center of the second signal output port 105. For example, when the first signal output port 104 is rectangular, its geometric center is the center of the rectangle; when the first signal output port 104 is circular, its geometric center is the circle center.

In this embodiment, the first RF chip 20 and the second RF chip 40 are arranged at intervals in the first direction L approximately. The second RF chip 40 and the second switch chip 50 are arranged at intervals in the second direction W approximately. The third signal input port 103 is located on the side of the second RF chip 40 away from the second switch chip 50, and the third signal output port 106 is located on the side of the second switch chip 50 away from the second RF chip 40. Specifically, the third signal input port 103, second RF chip 40, and second switch chip 50 are arranged in sequence in the second direction W approximately; the third signal output port 106, second switch chip 50, and second RF chip 40 are arranged in sequence in the second direction W approximately. With the above layout, the RF module 100 can shorten the signal transmission paths among the third signal input port 103, third power amplifier 410, second switch chip 50 and third signal output port 106, thus reducing the signal insertion loss. It also makes the arrangement among the third signal input port 103, second RF chip 40, second switch chip 50 and third signal output port 106 more compact and reasonable.

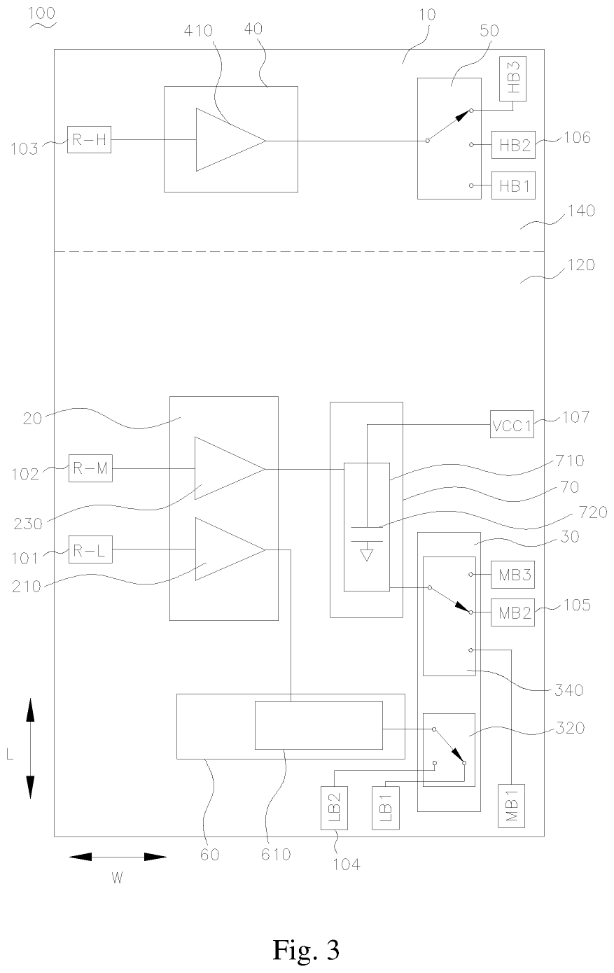

Referring to FIG. 3, the RF module 100 may further include a first matching circuit 60 and a second matching circuit 70, and the first matching circuit 60 and second matching circuit 70 are arranged on the substrate 10 and located in the first layout area 120 of the substrate 10. The first matching circuit 60 is connected between the first power amplifier 210 and the first switch chip 30, and is used for processing the RF signal output by the first power amplifier 210 and sending the processed RF signal to the first switch chip 30. Specifically, the first matching circuit 60 is connected between the first power amplifier 210 and the first switch unit 320, and is used for impedance conversion of the low-frequency RF signal output by the first power amplifier 210 to realize impedance matching, thus improving the impedance matching performance of the first RF chip 20.

As an embodiment, the first matching circuit 60 may include circuit elements such as inductor 610 and capacitor (not shown in the figure), which may be arranged on the substrate 10 in the form of discrete devices to form the first matching circuit 60. In some possible embodiments, the capacitor in the first matching circuit 60 may be a Surface Mounted Device (SMD), and the capacitor may be directly attached to the substrate 10. The inductor 610 in the first matching circuit 60 may be wound around the substrate 10 in the form of trace. For example, in the case that the substrate 10 adopts the structure of double metal layer, the inductor 610 is wound around the first metal layer 1100. The specific implementation of the first matching circuit 60 is not specifically limited in this embodiment.

The second matching circuit 70 is connected between the second power amplifier 230 and the first switch chip 30, and is used for processing the RF signal output by the second power amplifier 230 and sending the processed RF signal to the first switch chip 30. Specifically, the second matching circuit 70 is connected between the second power amplifier 230 and the second switch unit 340, and is used for impedance conversion of the intermediate frequency RF signal output by the second power amplifier 230 to realize impedance matching, thus improving the impedance matching performance of the first RF chip 20.

In the embodiment, as shown in FIG. 3, the first matching circuit 60 is located on the side of the first RF chip 20 away from the second RF chip 40, and is arranged at intervals with the first switch chip 30 in the second direction W; the second matching circuit 70 is located at the side of the first RF chip 20 facing the first switch chip 30, and is arranged at intervals with the first RF chip 20 in the second direction W. With the above layout, the RF module 100 can make the layout among the first RF chip 20, first matching circuit 60, second matching circuit 70 and first switch chip 30 more compact, thereby saving the layout area of the substrate 10 and shortening the transmission path of RF signals.

As an embodiment, the second matching circuit 70 may include a balun 710, a capacitor 720 and other circuit elements, which may be arranged on the substrate 10 in the form of discrete devices to form the second matching circuit 70. In some possible embodiments, the capacitor 720 in the second matching circuit 70 may be a Surface Mounted Device (SMD), and the capacitor 720 may be directly attached to the substrate 10. The balun 710 in second matching circuit 70 may be wound around substrate 10 in the form of trace. For example, in the case that the substrate 10 adopts the structure of double metal layer, the balun 710 is wound around the first metal layer 1100.

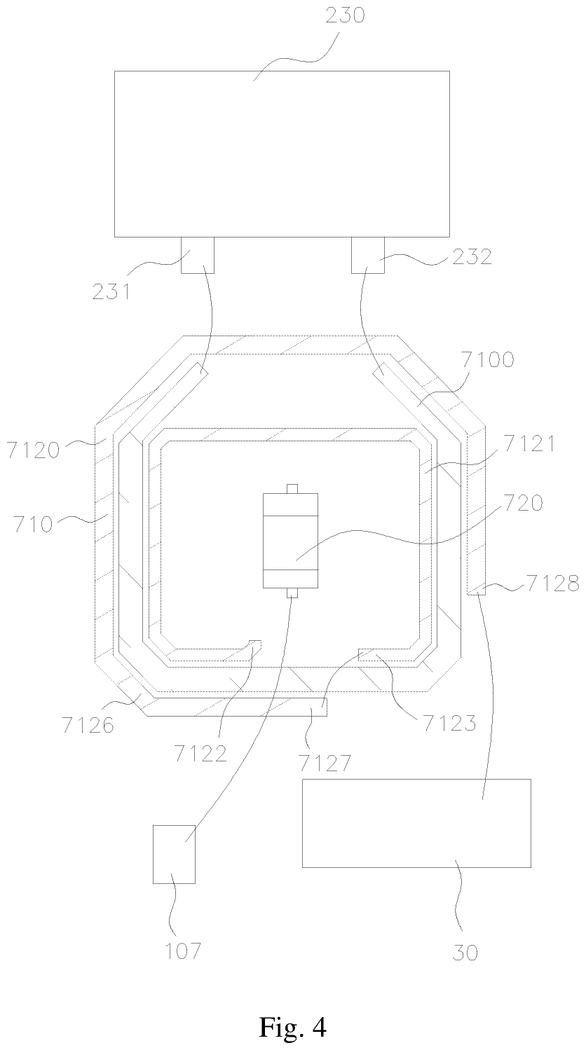

Specifically, referring to FIG. 4, one end of the capacitor 720 is connected to the first power supply port 107, and the other end is grounded. The balun 710 is connected between second power amplifier 230 and first switch chip 30, and surrounds the periphery of capacitor 720. In this embodiment, the capacitor 720 is arranged in the middle of the balun 710, so that the overall structure of the second matching circuit 70 is more compact and the layout area of the substrate 10 is saved. Further, in this embodiment, the second power amplifier 230 is connected to the first power supply port 107; one end of the capacitor 720 is also connected to the first power supply port 107, and the other end is grounded. Therefore, when the power supply voltage is input from the first power supply port 107 to the second power amplifier 230, the capacitor 720 can play a role of decoupling, thereby suppressing the fluctuation of the power supply voltage and making the RF signal output by the second power amplifier 230 more stable.

In this embodiment, the second power amplifier 230 is a differential amplifier circuit, i.e., the second power amplifier 230 has a first signal output end 231 and a second signal output end 232 for outputting a pair of differential signals. Specifically, the balun 710 may include a primary-side trace part 7100 and a secondary-side trace part 7120. The primary-side trace part 7100 surrounds the periphery of the capacitor 720 and is connected between the first signal output end 231 and the second signal output end 232. At least part of the secondary-side trace part 7120 surrounds the periphery of the primary-side trace part 7100; one end of the secondary-side trace part 7120 is grounded, and the other end is connected to the first switch chip 30. Therefore, the balun 710 in this embodiment converts a pair of differential signals output by the second power amplifier 230 into an RF signal and outputs it to the first switch chip 30. It should be noted here that “at least part of the secondary-side trace part 7120 surrounds the periphery of the primary-side trace part 7100” means that the whole secondary-side trace part 7120 may surround the periphery of the primary-side trace part 7100; or, a part of the secondary-side trace part 7120 may surround the outer periphery of the primary-side trace part 7100, and another part of the secondary-side trace part 7120 may surround the inner periphery of the primary-side trace part 7100. In this embodiment, the specific winding method of the secondary-side trace part 7120 is not specifically limited.

As an embodiment, the secondary-side trace part 7120 may include a first secondary-side trace 7121 and a second secondary-side trace 7126. The first secondary-side trace 7121 surrounds the periphery of the capacitor 720 and is located in the surrounding area defined by the primary-side trace part 7100. In other terms, the first secondary-side trace 7121 surrounds the inner periphery of the primary-side trace part 7100 and the second secondary-side trace 7126 surrounds the outer periphery of the primary-side trace part 7100. Specifically, the first end 7122 of the first secondary-side trace 7121 is grounded, and the second end 7123 of the first secondary-side trace 7121 is electrically connected to the first end 7127 of the second secondary-side trace 7126. The second end 7128 of the second secondary-side trace 7126 is connected to the first switch chip 30. Therefore, in this embodiment, the secondary-side trace part 7120 may include a first secondary-side trace 7121 wound around the inner periphery of the primary-side trace part 7100 and a second secondary-side trace 7126 wound around the outer periphery of the primary-side trace part 7100. In this way, the overall length of the secondary-side trace part 7120 is extended, i.e., the overall coupling length of the original secondary side of balun 710 is improved, and the output performance of balun 710 is optimized.

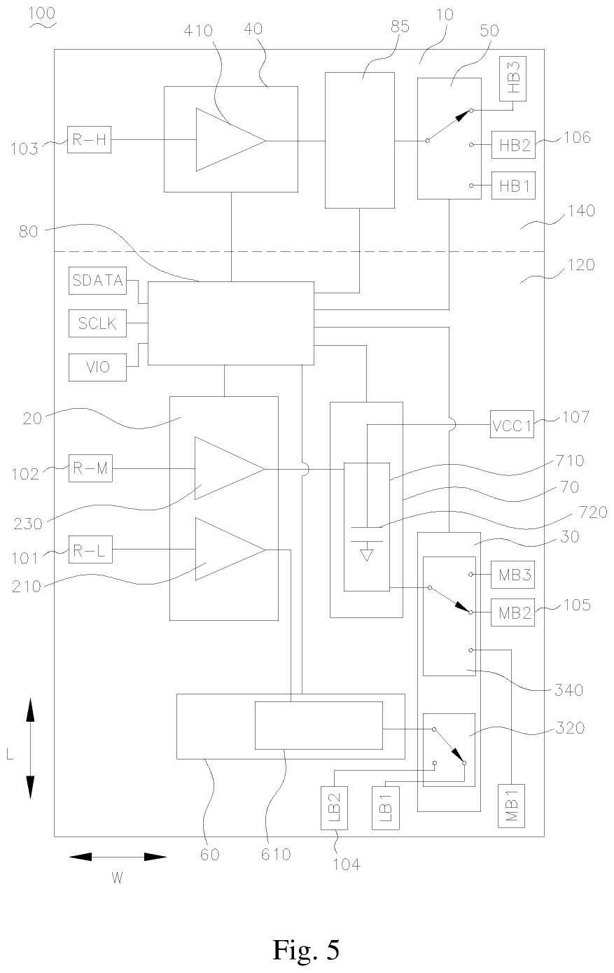

Referring to FIG. 5, the RF module 100 may further include a control chip 80 arranged on the substrate 10. Specifically, the control chip 80 may be attached to the substrate 10, inserted into the substrate 10, or welded to the substrate 10 by welding (for example, soldering). In this embodiment, the control chip 80 is connected to the first RF chip 20, first switch chip 30, second RF chip 40 and second switch chip 50, and is used for controlling the working states of the first RF chip 20, first switch chip 30, second RF chip 40 and second switch chip 50. Specifically, the control chip 80 may be connected to a plurality of control ports on the substrate 10, and receive control instructions sent from the outside through the plurality of control ports, and control the working states of the first RF chip 20, first switch chip 30, second RF chip 40 and second switch chip 50 according to the control instructions.

In this embodiment, the control chip 80 is located between the first RF chip 20 and the second RF chip 40. Specifically, the second RF chip 40, control chip 80 and first RF chip 20 are arranged at intervals in sequence in the first direction L approximately, so that the layout of the second RF chip 40, control chip 80 and first RF chip 20 is more compact and reasonable. In addition, the first RF chip 20, first switch chip 30, second RF chip 40 and second switch chip 50 are respectively arranged at the periphery of the control chip 80. In this way, when the control chip 80 connects the first RF chip 20, first switch chip 30, second RF chip 40 and second switch chip 50, the trace can be arranged more reasonably to avoid using too many jumper wires.

The RF module 100 may further include a third matching circuit 85, which is arranged on the substrate 10 and located in the second layout area 140 of the substrate 10. The third matching circuit 85 is located between the second RF chip 40 and the second switch chip 50, and connected to the third power amplifier 410 and the second switch chip 50 respectively. That is, the second RF chip 40, third matching circuit 85 and second switch chip 50 are arranged at intervals in the second direction W approximately, which can make the layout among the second RF chip 40, third matching circuit 85 and second switch chip 50 more compact, thereby saving the layout area of the substrate 10 and shortening the transmission path of RF signals. Specifically, the third matching circuit 85 is used to process the high-frequency RF signal output by the third power amplifier 410 and send the processed RF signal to the second switch chip 50. Because the third matching circuit 85 can be used for impedance conversion of high-frequency RF signals output by third power amplifier 410 to realize impedance matching, the impedance matching performance of second RF chip 40 is improved.

As an embodiment, the third matching circuit 85 may include circuit elements such as balun and capacitor (not shown in the figure), which may be arranged on the substrate 10 in the form of discrete devices to form the third matching circuit 85. In some possible embodiments, the capacitor in the third matching circuit 85 may be a Surface Mounted Device (SMD), and the capacitor may be directly attached to the substrate 10. Balun in third matching circuit 85 may be wound around the substrate 10 in the form of trace. For example, in the case that the substrate 10 adopts the structure of double metal layer, the balun is wound around the first metal layer 1100. Specifically, for the implementation of the third matching circuit 85, please refer to the circuit structure of the second matching circuit 70, which will not be repeated here.

The first embodiment of the present application provides an RF module 100, which may include a substrate 10, a first RF chip 20, a first switch chip 30, a second RF chip 40 and a second switch chip 50. The substrate 10 includes a first layout area 120 and a second layout area 140, and the first layout area 120 and the second layout area 140 are located in different parts of the substrate 10. The first RF chip 20 is arranged in the first layout area 120 and includes a first power amplifier 210 and a second power amplifier 230; the first power amplifier 210 is configured to receive a first input signal, the second power amplifier 230 is configured to receive a second input signal, and the frequency of the first input signal is lower than that of the second input signal. The first switch chip 30 is arranged in the first layout area 120 and connected to an output of the first power amplifier 210 and an output of the second power amplifier 230, respectively. The second RF chip 40 is arranged in the second layout area 140 and includes a third power amplifier 410; the third power amplifier 410 is configured to receive a third input signal, and the frequency of the third input signal is higher than that of the second input signal. The second switch chip 50 is arranged in the second layout area 140 and connected to an output end of the third power amplifier 410.

In this embodiment, the first RF chip 20 and the first switch chip 30 are arranged in the first layout area 120 of the substrate 10, the second RF chip 40 and the second switch chip 50 are arranged in the second layout area 140 of the substrate 10, and the first layout area 120 and the second layout area 140 are located in different parts of the substrate 10. For example, the first RF chip 20 and the first switch chip 30 may be located in the lower area of the substrate 10, and the second RF chip 40 and the second switch chip 50 may be located in the upper area of the substrate 10. Therefore, the RF module 100 of the present application shortens the transmission distance of RF signals between the first RF chip 20 and the first switch chip 30 and between the second RF chip 40 and the second switch chip 50 by arranging components in two areas separately, thus reducing the insertion loss, so that the RF signals have better output quality when output from the RF module 100.

Further, the first RF chip 20 may include a first power amplifier 210 and a second power amplifier 230, and the second RF chip 40 may include a third power amplifier 410, and the three power amplifiers may each amplify the received RF signals with different frequencies. For example, the first power amplifier 210 can amplify low-frequency RF signals, the second power amplifier 230 can amplify intermediate-frequency RF signals, and the third power amplifier 410 can amplify high-frequency RF signals, which makes the application scenarios of the RF module 100 more diverse.

Referring to FIG. 1 again, the second embodiment of the present application provides an RF module 100, which is an element that integrates two or more discrete devices such as RF switch, low noise amplifier, filter, duplexer, power amplifier, etc. into an independent module, so as to improve the integration and hardware performance, and to miniaturize the volume. Specifically, the RF module 100 can be applied to 4G and 5G communication devices such as smart phones, tablet computers and smart watches. In this embodiment, the RF module 100 may include a substrate 10, a first RF chip 20, a first switch chip 30, a second RF chip 40 and a second switch chip 50.

In this embodiment, the substrate 10 is provided with a signal input port and a signal output port. Specifically, the signal input port may include a first signal input port 101, a second signal input port 102, and a third signal input port 103. The distance between the first signal input port 101 and the second signal input port 102 is smaller than that between the first signal input port 101 and the third signal input port 103. Specifically, the first signal input port 101 is configured to input RF signals of the first frequency band, the second signal input port 102 is configured to input RF signals of the second frequency band, and the third signal input port 103 is configured to input RF signals of the third frequency band. The frequency of the first band is less than that of the second band, and the frequency of the second band is less than that of the third band.

The signal output port includes a first signal output port 104, a second signal output port 105 and a third signal output port 106. The distance between the first signal output port 104 and the second signal output port 105 is smaller than that between the first signal output port 104 and the third signal output end 106.

The first RF chip 20 is arranged on the substrate 10, and the first RF chip 20 is connected with the first signal input port 101 and the second signal input port 102. The second RF chip 40 is arranged on the substrate 10, and the second RF chip 40 is connected with the third signal input port 103. The first switch chip 30 is arranged on the substrate 10 and connected with the first RF chip 30, the first signal output port 104 and the second signal output port 105. The second switch chip 50 is arranged on the substrate 10 and connected with the second RF chip 40 and the third signal output port 106.

In this embodiment, the RF signal input by the first signal input port 101 may be a low-band RF signal, the RF signal input by the second signal input port 102 may be a medium-band RF signal, and the RF signal input by the third signal input port 103 may be a high-band RF signal.

In this embodiment, the signal output port may include a first signal output port 104, a second signal output port 105 and a third output port 106. And, the number of first signal output port 104, the number of second signal output port 105 and the number of third signal output port 106 is plural, i.e., more than or equal to two. As a preferred embodiment, the first signal output port 104 can output RF signals in low frequency band, the second signal output port 105 can output RF signals in middle frequency band, and the third signal output port 106 can output RF signals in high frequency band.

In this embodiment, the distance between the first signal input port 101 and the second signal input port 102 is smaller than the distance between the first signal input port 101 and the third signal input port 103. Therefore, when the first RF chip 20 and the second RF chip 40 are arranged on the substrate 10, the first signal input port 101 and second signal input port 102 can be closer to the first RF chip 20, the third signal input port 103 can be closer to the second RF chip 40, so that the layout of the trace between the first signal input port 101 and first RF chip 20, the trace between the second signal input port 102 and first RF chip 20, and the trace between the third signal input port 103 and second RF chip 40 can be more reasonable. It should be noted that “the distance between the first signal input port 101 and second signal input port 102” can be understood as the straight-line distance between the geometric center of the first signal input port 101 and the geometric center of the second signal input port 102. For example, when the first signal input port 101 is rectangular, its geometric center is the center of the rectangle; when the first signal input port 101 is circular, its geometric center is the circle center.

In this embodiment, the second switch chip 50 is connected to the third signal output port 106, and the distance between the first signal output port 104 and the second signal output port 105 is smaller than that between the first signal output port 104 and the third signal output port 106. Therefore, when the first switch chip 30 and second switch chip 50 are arranged on the substrate 10, the first signal output port 104 and second signal output port 105 can be closer to the first switch chip 30, the third signal output port 106 can be closer to the second switch chip 50, so that the layout of the trace between the first signal output port 104 and first switch chip 30, the trace between the second signal output port 105 and first switch chip 30, and the trace between the third signal output port 106 and second switch chip 50 can be more reasonable. It should be noted that “the distance between the first signal output port 104 and the second signal output port 105” can be understood as the straight-line distance between the geometric center of the first signal output port 104 and the geometric center of the second signal output port 105. For example, when the first signal output port 104 is rectangular, its geometric center is the center of the rectangle; when the first signal output port 104 is circular, its geometric center is the circle center.

In this embodiment, the first RF chip 20 may include a first power amplifier 210 and a second power amplifier 230. The first power amplifier 210 is connected with the first signal input port 101 and configured to receive the input signal of the first signal input port 101. The second power amplifier 230 is connected with the second signal input port 102 and configured to receive the input signal of the second signal input port 102. The second RF chip 40 includes a third power amplifier 410, which is connected with the third signal input port 103 and configured to receive the input signal of the third signal input port 103. The distance between the first RF chip 20 and the first switch chip 30 is smaller than that between the first RF chip 20 and the second switch chip 40. Specifically, in this embodiment and other embodiments, “the distance between two elements” refers to the distance between the geometric centers of two elements.

In this embodiment, the distance between the first RF chip 20 and the first switch chip 30 is smaller than that between the first RF chip 20 and the second switch chip 40, and the first RF chip 20 is connected with the first switch chip 30. Therefore, by reducing the transmission distance of RF signals between the first RF chip 20 and the first switch chip 30, and the transmission distance between the second RF chip 40 and the second switch chip 50, the insertion loss and interference of RF signals are reduced, so that the RF signals output from the RF module 100 have better output quality.

In this embodiment, the distance between the first signal input port 101 and the first RF chip 20 is smaller than the distance between the first signal input port 101 and the second RF chip 40. The first signal input port 101 inputs the RF signal of the first frequency band, and the second signal input port 102 inputs the RF signal of the second frequency band. Therefore, in this embodiment, both the RF signals of the first frequency band and the RF signals of the second frequency band are amplified by the first RF chip 20, so as to reduce the transmission distance between the RF signals of the first frequency band and the RF signals of the second frequency band from the input port to the first RF chip 20, and thus reducing the insertion loss and interference of the RF signals.

In this embodiment, the distance between the first signal output port 104 and the first switch chip 30 is smaller than the distance between the first signal output port 104 and the second switch chip 50. The first signal output port 104 outputs the RF signal of the first frequency band, and the second signal output port 105 outputs the RF signal of the second frequency band. Therefore, in this embodiment, both the RF signals of the first frequency band and the RF signals of the second frequency band are turned on and off by the first switch chip 30, so as to reduce the transmission distance of the RF signals of the first frequency band and the RF signals of the second frequency band from the switch chip to the output port, and thus reducing the insertion loss and interference of the RF signals. To sum up, for the RF module 100 provided by this embodiment, by reducing the transmission distance of the RF signal on the input path and the transmission distance on the output path, the insertion loss and interference of the RF signal are reduced, so that the RF signal has better output quality when it is output from the RF module 100.

It should be noted here that for other features of the substrate 10, first RF chip 20, first switch chip 30, second RF chip 40 and second switch chip 50 in this embodiment, please refer to the features of substrate 10, first RF chip 20, first switch chip 30, second RF chip 40 and second switch chip 50 in the first embodiment. In order to save space, it won't be repeated here. Similarly, in the case of no conflict, the substrate 10, first RF chip 20, first switch chip 30, second RF chip 40 and second switch chip 50 in the first embodiment may also be provided with the features of the substrate 10, first RF chip 20, first switch chip 30, second RF chip 40 and second switch chip 50. Features in the two embodiments can be combined with each other.

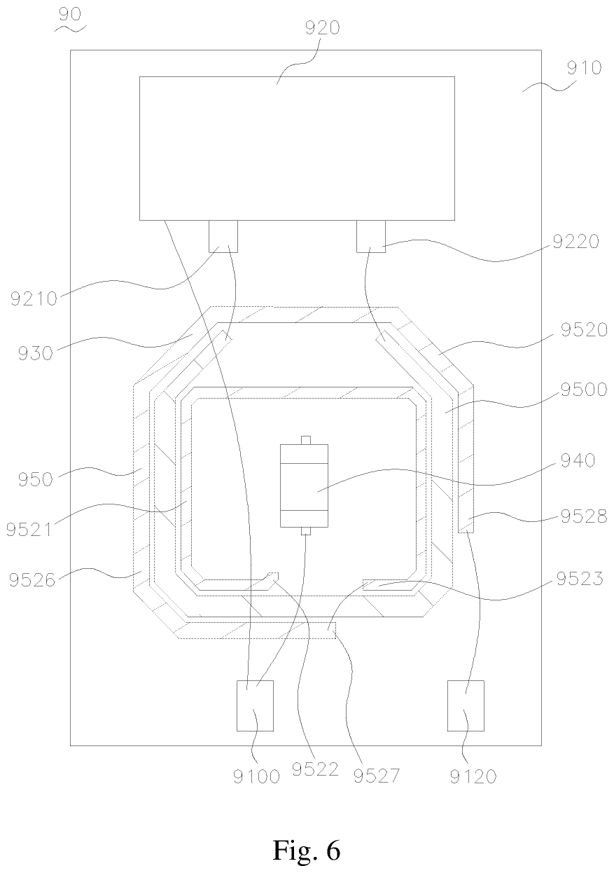

Referring to FIG. 6, the third embodiment of the present application provides an RF module 90, which is an element that integrates two or more discrete devices such as RF switch, low noise amplifier, filter, duplexer, power amplifier, etc. into an independent module, so as to improve the integration and hardware performance, and to miniaturize the volume. Specifically, the RF module 90 can be applied to 4G and 5G communication devices such as smart phones, tablet computers and smart watches. In this embodiment, the RF module 90 may include a substrate 910, an RF chip 920 and a matching circuit 930. And, the substrate 910 is provided with a power supply port 9100 and a signal output port 9120. The RF chip 920 is arranged on the substrate 910 and connected to the power supply port 9100. The matching circuit 930 is arranged on the substrate 910 and connected between the RF chip 920 and signal output port 9120. The matching circuit 930 includes a first capacitor 940 and a first balun 950. One end of the first capacitor 940 is connected to the power supply port 9100, and the other end is grounded. The first balun 950 is connected between the RF chip 920 and the signal output port 9120 and surrounds the periphery of the first capacitor 940.

Therefore, in this embodiment, the first capacitor 940 is arranged in the middle of the first balun 950, which makes the overall structure of the matching circuit 930 more compact and saves the layout area of the substrate 910. Further, the RF chip 920 in this embodiment is connected to the power supply port 9100; one end of the first capacitor 940 is also connected to the power supply port 9100, and the other end is grounded. Therefore, when the power supply voltage is input from the power supply port 9100 to the RF chip 920, the first capacitor 940 can play a role of decoupling, thereby suppressing the fluctuation of the power supply voltage and making the RF signal output by the RF chip 920 more stable.

Next, each module included in the RF module 90 in the third embodiment will be introduced.

The substrate 910 is roughly rectangular, and is used to fixedly support components in the RF module 90 (for example, RF chip 920 and matching circuit 930). Specifically, the substrate 910 may be a copper-clad laminate, and a circuit can be printed on the surface of the substrate 910 by processing the copper-clad laminate with holes, electroless copper plating, copper electroplating and etching.

In this embodiment, the substrate 910 is provided with a power supply port 9100 and a signal output port 9120. And, the power supply port 9100 is used to connect external power supply, and the external power supply supplies power to components on the substrate 910 through power supply port 9100. And, the external power supply can be used to provide power supply voltage, and the power supply voltage may be 3.3V, 5V, 12V, etc., which is not specifically limited in this embodiment. The signal output port 9120 is used to receive an output signal, wherein the output signal may be an RF signal with a specified frequency. The specified frequency of the RF signal is determined by the communication equipment to which the RF module 90 is specifically applied. For example, if the communication device works in N77 frequency band, the specified frequency may be 3.3 GHZ-4.2 GHz. If the communication equipment works in N78 frequency band, the specified frequency may be 3.3 GHZ-3.8 GHz. If the communication equipment works in N79 frequency band, the specified frequency may be 4.5 GHZ-5 GHz. In this embodiment, the output signal of the signal output port 9120 is not specifically limited.

For other features of the substrate 910 in this embodiment, please refer the features of the substrate 10 in the first embodiment. In order to save space, it won't be repeated here. Similarly, in the case of no conflict, the substrate 10 in the first embodiment may also have the features of the substrate 910 in the third embodiment. Features in the two embodiments can be combined with each other.

The RF chip 920 is arranged on the substrate 910, and is used for power amplification of the input RF signal. Specifically, the RF chip 920 may be attached to the substrate 910, inserted into the substrate 910, or welded to the substrate 910 by welding (for example, soldering). In this embodiment, the RF chip 920 is connected to the power supply port 9100, and the power supply port 9100 is used for supplying power to the RF chip 920.

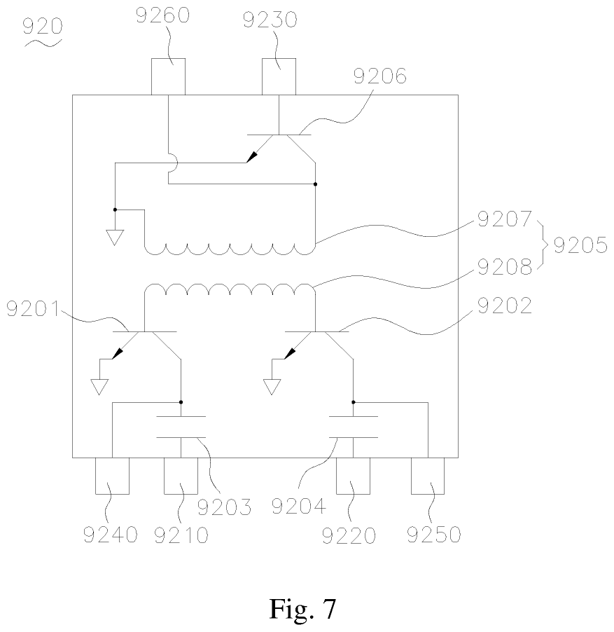

In this embodiment, the RF chip 920 adopts a circuit structure of a two-stage differential amplifier circuit. Referring to FIG. 7, the RF chip 920 has a first signal output end 9210, a second signal output end 9220, a signal input end 9230, a first connection end 9240, a second connection end 9250 and a power supply end 9260. The first signal output end 9210 and second signal output end 9220 are used to output a pair of differential signals. The signal input end 9230 is connected to a signal input port (not shown in the figure) on the substrate 910 for inputting the RF signal to be processed. The first connection end 9240, second connection end 9250 and power supply end 9260 are connected to the power supply port 9100 for supplying power to the components inside the RF chip 920. Specifically, the RF chip 920 may include a first transistor 9201, a second transistor 9202, a third capacitor 9203, a fourth capacitor 9204, a second balun 9205 and a third transistor 9206.

In FIG. 7, the input end of the third transistor 9206 is connected to the signal input end 9230, and the output end of the third transistor 9206 is connected to the second balun 9205; the output end of the third transistor 9206 is also connected to the power supply end 9260, i.e., the power supply end 9260 is used to supply power to the third transistor 9206. Thus, the third transistor 9206 constitutes a first stage amplifier circuit. Specifically, the third transistor 9206 may be a bipolar junction transistor (BJT), the base of the BJT is the input end of the third transistor 9206, the collector is the output end of the third transistor 9206, and the emitter is grounded.

The second balun 9205 includes a primary side 9207 and a secondary side 9208 coupled with each other; one end of the primary side 9207 is connected to the output end of the third transistor 9206, and the other end of the primary side 9207 is grounded. The secondary side 9208 is connected between the input end of the first transistor 9201 and the input end of the second transistor 9202. Therefore, the second balun 9205 is used to convert an RF signal processed by the third transistor 9206 into a pair of RF signals to be output to the first transistor 9201 and the second transistor 9202 respectively.

The input end of the first transistor 9201 is connected to one end of the secondary side 9208, and the output end of the first transistor 9201 is connected to the first signal output end 9210 via the third capacitor 9203. The output end of the first transistor 9201 is also connected to the first connection end 9240, i.e., the first connection end 9240 is used to supply power to the first transistor 9201. The input end of the second transducer 9202 is connected to the other end of the secondary side 9208, and the output end of the second transducer 9202 is connected to the second signal output end 9220 via the fourth capacitor 9204. The output end of the second signal output end 9220 is also connected to the second connection end 9250, i.e., the second connection end 9250 is used to supply power to the second transistor 9202. Therefore, the first transistor 9201 and the second transistor 9202 constitute a second stage amplifier circuit, and the amplifier circuit is a differential amplifier circuit. Specifically, the first transistor 9201 and the second transistor 9202 may be BJT of the same model, the bases of the BJT are respectively the input ends of the first transistor 9201 and the second transistor 9202, the collectors are respectively the output ends of the first transistor 9201 and the second transistor 9202, and the emitters are grounded.

One end of the third capacitor 9203 is connected to the output end of the first transistor 9201, and the other end is connected to the first signal output end 9210. One end of the fourth capacitor 9204 is connected to the output end of the second transistor 9202, and the other end is connected to the second signal output end 9220. The third capacitor 9203 is used to filter the RF signal output by the first transistor 9201, and the fourth capacitor 9204 is used to filter the RF signal output by the second transistor 9202, so that the differential signal output from the RF chip 920 is more stable.

It should be noted here that, in this embodiment, the distribution positions of the first signal output end 9210, second signal output end 9220, signal input end 9230, the first connection end 9240, second connection end 9250 and power supply end 9260 in the RF chip 920 are not specifically limited. And there are no specific limitations on the integration methods of the first transistor 9201, second transistor 9202, the third capacitor 9203, fourth capacitor 9204, second balun 9205 and third transistor 9206 in the RF chip 920.

Referring to FIG. 6 again, the matching circuit 930 is arranged on the substrate 910 and connected between the RF chip 920 and the signal output port 9120, and is used for processing the RF signal output by the RF chip 920 and sending the processed RF signal to the signal output port 9120. Specifically, the matching circuit 930 may be used for impedance conversion of the RF signal output by the RF chip 920 to realize impedance matching, which improves the impedance matching performance of the RF chip 920.

In this embodiment, the matching circuit 930 may include a first capacitor 940 and a first balun 950. The first capacitor 940 and the first balun 950 may be arranged on the substrate 910 in the form of discrete devices to form the matching circuit 930. In some possible embodiments, the first capacitor 940 in the matching circuit 930 may be a Surface Mounted Device (SMD), and the first capacitor 940 may be directly attached to the substrate 910. The first balun 950 in the matching circuit 930 may be wound around the substrate 910 in the form of trace.

Specifically, one end of the first capacitor 940 is connected to the power supply port 9100, and the other end is grounded. The first balun 950 is connected between the RF chip 920 and the signal output port 9120 and surrounds the periphery of the first capacitor 940. In this embodiment, the first capacitor 940 is arranged in the middle of the first balun 950, which makes the overall structure of the matching circuit 930 more compact and saves the layout area of the substrate 910. Further, the RF chip 920 in this embodiment is connected to the power supply port 9100; one end of the first capacitor 940 is also connected to the power supply port 9100, and the other end is grounded. Therefore, when the power supply voltage is input from the power supply port 9100 to the RF chip 920, the first capacitor 940 can play a role of decoupling, thereby suppressing the fluctuation of the power supply voltage and making the RF signal output by the RF chip 920 more stable.

In this embodiment, the first balun 950 may include a primary-side trace part 9500 and a secondary-side trace part 9520. The primary-side trace part 9500 surrounds the periphery of the first capacitor 940 and is connected between the first signal output end 9210 and the second signal output end 9220. At least part of the secondary-side trace part 9520 surrounds the periphery of the primary-side trace part 9500; one end of the secondary-side trace part 9520 is grounded and the other end is connected to the signal output port 9120. Therefore, in this embodiment, the first balun 950 converts a pair of differential signals output by the RF chip 920 into an RF signal and outputs it to the signal output port 9120. It should be noted here that “at least part of the secondary-side trace part 9520 surrounds the periphery of the primary-side trace part 9500” means that the whole secondary-side trace part 9520 may surround the periphery of the primary-side trace part 9500; or, a part of the secondary-side trace part 9520 may surround the outer periphery of the primary-side trace part 9500, and another part of the secondary-side trace part 9520 may surround the inner periphery of the primary-side trace part 9500. In this embodiment, the specific winding method of the secondary-side trace part 9520 is not specifically limited.

As an embodiment, the secondary-side trace part 9520 may include a first secondary-side trace 9521 and a second secondary-side trace 9526. The first secondary-side trace 9521 surrounds the periphery of the first capacitor 940 and is located in the surrounding area defined by the primary-side trace part 9500. In other terms, the first secondary-side trace 9521 surrounds the inner periphery of the primary-side trace part 9500, and the second secondary-side trace 9526 surrounds the outer periphery of the primary-side trace part 9500. Specifically, the first end 9522 of the first secondary-side trace 9521 is grounded, and the second end 9523 of the first secondary-side trace 9521 is electrically connected to the first end 9527 of the second secondary-side trace 9526. The second end 9528 of second secondary-side trace 9526 is connected to the signal output port 9120. Therefore, in this embodiment, the secondary-side trace part 9520 may include a first secondary-side trace 9521 wound around the inner periphery of the primary-side trace part 9500 and a second secondary-side trace 9526 wound around the outer periphery of the primary-side trace part 9500. Thus, the overall length of the secondary-side trace part 9520 is prolonged, i.e., the overall coupling length of the original secondary side of the first balun 950 is improved, and the output capability of the first balun 950 is ensured.

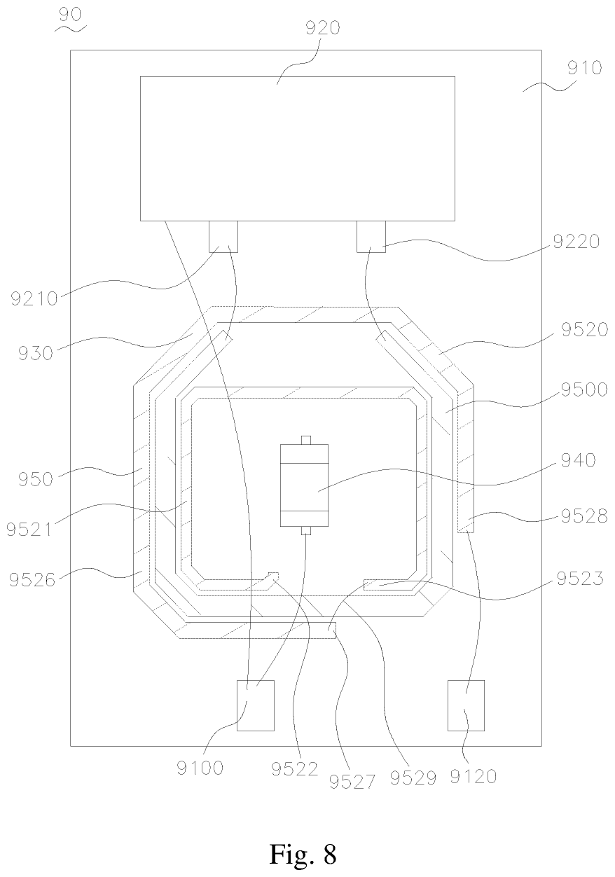

In some possible embodiments, referring to FIG. 8, the secondary-side trace part 9520 may further include a first jumper wire 9529, which spans the primary-side trace part 9500, and is connected between the second end 9523 of the first secondary-side trace 9521 and the first end 9527 of the second secondary-side trace 9526.

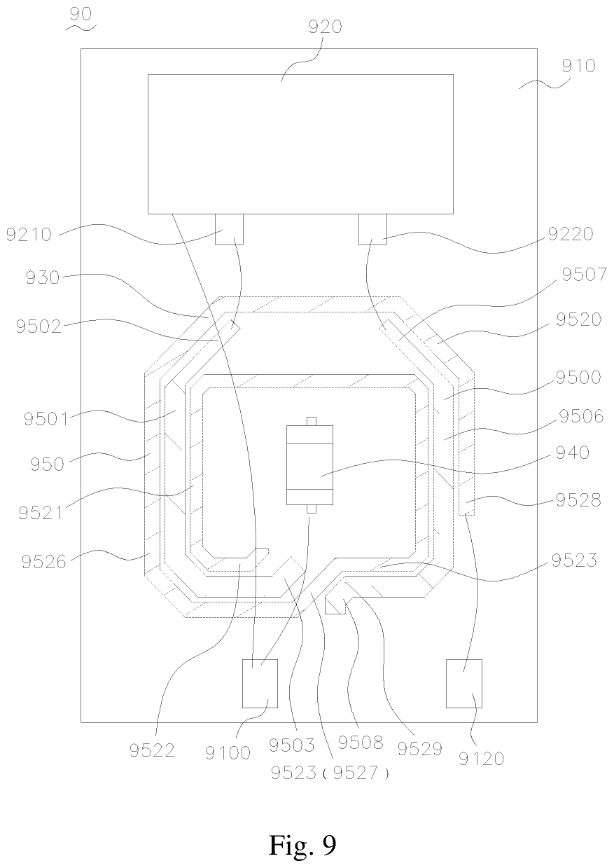

In other possible embodiments, referring to FIG. 9, the primary-side trace part 9500 may include a first primary-side trace 9501 and a second primary-side trace 9506. The first primary-side trace 9501 and the second primary-side trace 9506 respectively surround the two sides of the first capacitor 940 to jointly define the surrounding area. Specifically, the first end 9502 of the first primary-side trace 9501 is connected to the first signal output end 9210, and the second end 9503 of the first primary-side trace 9501 is grounded. The first end 9507 of the second primary-side trace 9506 is connected to the second signal output end 9220, and the second end 9508 of the second primary-side trace 9506 is grounded; the second end 9503 of first primary-side trace 9501 and second end 9508 of second primary-side trace 9506 are arranged at intervals.

The second end 9523 of the first secondary-side trace 9521 is directly connected with the first end 9527 of the second secondary-side trace 9526. For example, the first secondary-side trace 9521 and the second secondary-side trace 9526 may belong to the same trace. The first secondary-side trace 9521 and the second secondary-side trace 9526 are directly connected and then pass through the gap between the second end 9503 of the first primary-side trace 9501 and the second end 9508 of the second primary-side trace 9506. Therefore, compared with the implementation of connecting the first secondary-side trace 9521 and the second secondary-side trace 9526 with the jumper wire in the embodiment of FIG. 8, the first secondary-side trace 9521 and the second secondary-side trace 9526 in this embodiment do not need to use extra trace when they are connected, so that the first balun 950 can work more stably and save the cost of hardware of the RF module 90.

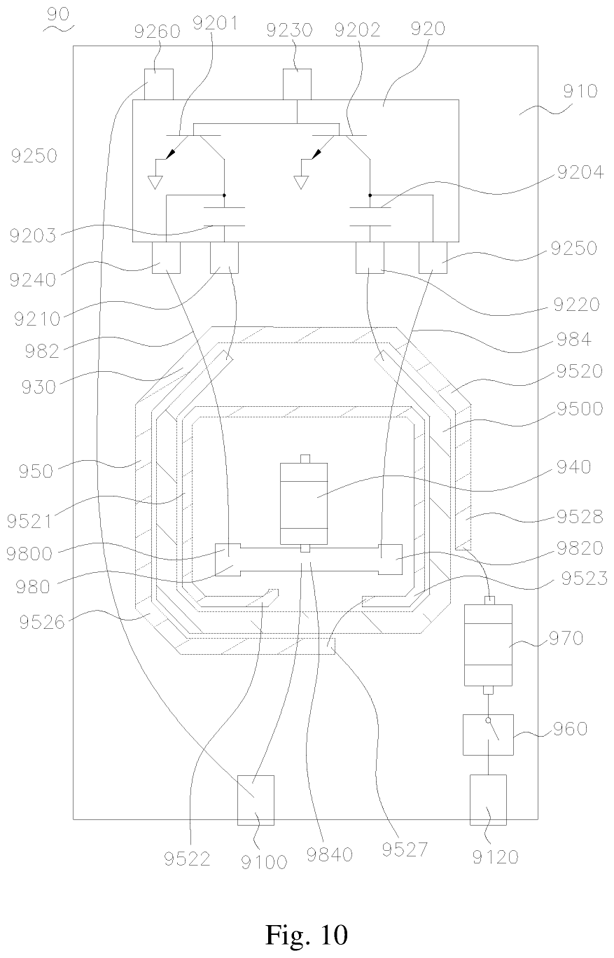

Referring to FIG. 10, the RF module 90 may further include a switch chip 960 arranged on the substrate 910. The end of the secondary-side trace part 9520 away from the ground (i.e., the second end 9528 of the secondary-side trace 9526) is connected to the signal output port 9120 through the switch chip 960. The switch chip 960 is used to control the output state of RF signals processed by first balun 950. For example, when the switch chip 960 is on, the RF signal processed by the first balun 950 can be smoothly output from the RF module 90. On the contrary, when the switch chip 960 is off, the RF signal processed by the first balun 950 cannot be output from the RF module 90. Specifically, the switch chip 960 may be attached to the substrate 910, inserted into the substrate 910, or welded to the substrate 910 by welding (for example, soldering).

The matching circuit 930 may further include a second capacitor 970, which is arranged on the substrate 910. The second capacitor 970 is connected between the end of the secondary-side trace part 9520 away from the ground (i.e., the second end 9528 of the second secondary-side trace 9526) and the switch chip 960, and is used for filtering the RF signal output by the first balun 950, so that the RF signal output from the RF module 90 is more stable. Specifically, the second capacitor 970 may be a Surface Mounted Device, and the second capacitor 970 may be directly attached to the substrate 910.

In this embodiment, the matching circuit 930 may further include a wiring part 980, a second jumper wire 982 and a third jumper wire 984. The wiring part 980 is located in the surrounding area defined by the primary-side trace part 9500 and is electrically connected with the power supply port 9100. The end of the first capacitor 940 away from the ground is connected to the power supply port 9100 through the wiring part 980. The second jumper wire 982 is connected between first connection end 9240 and wiring part 980, and the third jumper wire 984 is connected between the second connection end 9250 and wiring part 980. Therefore, the RF module 90 supplies power to the first connection end 9240 via the second jumper wire 982, and supplies power to the second connection end 9250 via the third jumper wire 984. Further, the second jumper wire 982 may be equivalent to an inductor between the power supply port 9100 and the first connection end 9240. The inductor and the first capacitor 940 form an LC resonant circuit, thus improving the impedance matching performance of the RF chip 920. Similarly, the third jumper wire 984 may be equivalent to an inductor between the power supply port 9100 and the second connection end 9250. The inductor and the first capacitor 940 form an LC resonant circuit, thus improving the impedance matching performance of the RF chip 920.

In some possible embodiments, the wiring part 980 may include a first wiring end 9800, a second wiring end 9820 and a first trace 9840. The first wiring end 9800 and first connection end 9240 are located at one side of the first capacitor 940, and the second jumper wire 982 is connected between the first wiring end 9800 and the first connection end 9240. The second wiring end 9820 and second connection end 9250 are located on the other side of the first capacitor 940, and the third jumper wire 984 is connected between the second wiring end 9820 and the second connection end 9250. Since the first wiring end 9800 and the second wiring end 9820 are located on opposite sides of the first capacitor 940, the situation that the output performance of the RF chip 920 is reduced due to the intersection of the second jumper wire 982 and the third jumper wire 984 during connection is avoided.

The first trace 9840 is connected between the first wiring end 9800 and the second wiring end 9820, and is electrically connected with the power supply port 9100. The end of the first capacitor 940 away from the ground is connected to the power supply port 9100 via the first trace 9840. In some possible embodiments, the first wiring end 9800 and second wiring end 9820 may be opposite ends of the first trace 9840, respectively. The first wiring end 9800, second wiring end 9820 and first trace 9840 are different parts on the same trace, so that the first capacitor 940, second jumper wire 982 and third jumper wire 984 can be connected more reliably. The specific implementation of the wiring part 980 is not specifically limited.

The third embodiment of the present application provides an RF module 90, which may include a substrate 910, an RF chip 920 and a matching circuit 930. And, the substrate 910 is provided with a power supply port 9100 and a signal output port 9120. The RF chip 920 is arranged on the substrate 910 and connected to the power supply port 9100. The matching circuit 930 is arranged on the substrate 910 and connected between the RF chip 920 and signal output port 9120. The matching circuit 930 includes a first capacitor 940 and a first balun 950. One end of the first capacitor 940 is connected to the power supply port 9100, and the other end is grounded. The first balun 950 is connected between the RF chip 920 and the signal output port 9120 and surrounds the periphery of the first capacitor 940.

Therefore, in this embodiment, the first capacitor 940 is arranged in the middle of the first balun 950, which makes the overall structure of the matching circuit 930 more compact and saves the layout area of the substrate 910. Further, the RF chip 920 in this embodiment is connected to the power supply port 9100; one end of the first capacitor 940 is also connected to the power supply port 9100, and the other end is grounded. Therefore, when the power supply voltage is input from the power supply port 9100 to the RF chip 920, the first capacitor 940 can play a role of decoupling, thereby suppressing the fluctuation of the power supply voltage and making the RF signal output by the RF chip 920 more stable.

In the specification of this application, certain terms are used throughout the description and the claims to refer to particular components. It should be understood by those skilled in the art that hardware manufacturers may use different terms to refer to the those components. In the specification and claims, components are not distinguished by the difference of names, but by the difference of functions. As mentioned in the whole specification and claims, “including” is an open-ended term, which should be interpreted as “including but not limited to”; “Roughly” and “approximately” indicate that those skilled in the art can solve the technical problems within a certain error range and basically achieve the desired technical effects.

For the description of this application, it should be understood that the orientations or positional relationships indicated by the terms “up”, “down”, “front”, “back”, “left”, “right” and “inside” are based on the orientations or positional relationships shown in the attached drawings, only for convenience of describing the present invention and simplifying the description, and do not indicate or imply that the said device or element must have a specific orientation, be constructed or operated in a particular orientation, and therefore cannot be understood as a limitation of the present invention.

In the description of the present application, unless otherwise specified and defined, the terms “installation”, “connected with”, “connected to” and “fixed” should be understood in a broad sense. For example, they may be fixedly connected, detachably connected or integrally connected, or may be mechanically connected or electrically connected, or may be directly connected or indirectly connected through an intermediate medium. Or it may be internal communication of two elements, or only in surface contact. For those of ordinary skill in the art, the specific meanings of the above terms in the present application may be understood in specific situations.

In the description of this specification, the terms “one embodiment”, “some embodiments”, “example”, “specific example” or “some examples” mean that specific features, structures, materials or characteristics described in combination of this embodiment or example are included in at least one embodiment or example of this application. In this specification, the schematic descriptions of the above terms are not necessarily aimed at the same embodiment or example. Moreover, the specific features, structures, materials or characteristics described may be combined in any one or more embodiments or examples in an appropriate manner. In addition, those skilled in the art can combine different embodiments or examples and features of different embodiments or examples described in this specification without contradicting each other.

Furthermore, the terms “first” and “second” are used for descriptive purposes only and cannot be understood as indicating or implying relative importance or implicitly indicating the number of technical features indicated. Thus, a feature defined by “first” or “second” may explicitly or implicitly includes at least one feature. For the description of the present invention, the meaning of “plurality” is at least two, e. g., two or three, unless otherwise specifically defined.

The above embodiments are merely used to illustrate the technical solution of the present application, rather than limit it. Although the application has been described in detail with reference to the foregoing embodiments, it should be understood by those skilled in the art that it is still possible to modify the technical solutions described in the foregoing embodiments, or equivalently replace some technical features thereof. These modifications and equivalents do not make the nature of the corresponding technical solution deviates from the spirit and scope of the present application, and shall be included in the protection scope of the present application.

What is claimed is:

1. An RF module, comprising:
a substrate, the substrate comprises a first layout area and a second layout area, the first layout area and the second layout area are located at different parts of the substrate respectively;
a first RF chip, the first RF chip is arranged in the first layout area and comprises a first power amplifier and a second power amplifier, the first power amplifier is configured to receive a first input signal, the second power amplifier is configured to receive a second input signal, and a frequency of the first input signal is lower than that of the second input signal;
a first switch chip, the first switch chip is arranged in the first layout area and connected to an output end of the first power amplifier and an output end of the second power amplifier respectively;
a second RF chip, the second RF chip is arranged in the second layout area and comprises a third power amplifier, the third power amplifier is configured to receive a third input signal, and a frequency of the third input signal is higher than that of the second input signal; and
a second switch chip, the second switch chip is arranged in the second layout area and connected to an output end of the third power amplifier.

2. The RF module of claim 1, wherein the first layout area and the second layout area are arranged in parallel on the substrate and are adjacent to each other.

3. The RF module of claim 1, wherein the substrate is further provided with a first signal input port, a second signal input port and a third signal input port, the first signal input port and the second signal input port are arranged in the first layout area and positioned on a side of the first RF chip away from the first switch chip;
the first signal input port is connected to an input end of the first power amplifier, and the second signal input port is connected to an input end of the second power amplifier; and
the third signal input port is arranged in the second layout area and positioned on a side of the second RF chip away from the second switch chip; the third signal input port is connected to an input end of the third power amplifier, and the distance between the first signal input port and the second signal input port is smaller than that between the second signal input port and the third signal input port.

4. The RF module of claim 3, wherein the first signal input port, the second signal input port and the third signal input port are arranged at intervals in a first direction; and
the first signal input port, the first RF chip and the first switch chip are sequentially arranged in a second direction; the second signal input port, the first RF chip and the first switch chip are sequentially arranged in the second direction; the third signal input port, the second RF chip and the second switch chip are sequentially arranged in the second direction, and the second direction intersects with the first direction.

5. The RF module of claim 1, wherein the first switch chip comprises a first switch unit and a second switch unit, the first switch unit is connected to the output end of the first power amplifier, and the second switch unit is connected to the output end of the second power amplifier; and
the substrate is also provided with a first signal output port and a second signal output port, the first signal output port is arranged in the first layout area and connected to the first switch unit; the second signal output port is arranged in the first layout area and connected to the second switch unit.

6. The RF module of claim 5, wherein the substrate is further provided with a third signal output port, the third signal output port is arranged in the second layout area and connected to the second switch chip, and the distance between the first signal output port and the second signal output port is smaller than that between the first signal output port and the third signal output port.

7. The RF module of claim 1, wherein the first RF chip and the second RF chip are arranged at intervals in a first direction, the first RF chip and the first switch chip are arranged at intervals in a second direction, and the second RF chip and the second switch chip are arranged at intervals in the second direction, and the first direction intersects with the second direction.

8. The RF module of claim 7, further comprising a first matching circuit and a second matching circuit, the first matching circuit and the second matching circuit are arranged in the first layout area; the first matching circuit is positioned on a side of the first RF chip away from the second RF chip, and the first matching circuit and the first switch chip are arranged at intervals in the second direction; the second matching circuit is positioned on a side of the first RF chip facing the first switch chip, and the second matching circuit and the first RF chip are arranged at intervals in the second direction; and
the first matching circuit is connected between the first power amplifier and the first switch chip, and the second matching circuit is connected between the second power amplifier and the first switch chip.

9. The RF module of claim 8, wherein the first matching circuit comprises an inductor, and the second matching circuit comprises a balun; the substrate comprises a first metal layer and a second metal layer arranged at intervals; the inductor and the balun are arranged on the first metal layer; and the signal input port and signal output port are arranged on the second metal layer.

10. The RF module of claim 8, wherein the substrate is further provided with a first power supply port, and the second matching circuit comprises a capacitor and a balun;
one end of the capacitor is connected to the first power supply port, and another end is grounded;
the balun is connected between the second power amplifier and the first switch chip and surrounds a periphery of the capacitor.

11. The RF module of claim 10, wherein the second power amplifier has a first signal output end and a second signal output end;
the balun comprises a primary-side trace part and a secondary-side trace part; the primary-side trace part surrounds the periphery of the capacitor and is connected between the first signal output end and the second signal output end; and
at least part of the secondary-side trace part surrounds a periphery of the primary-side trace part, one end of the secondary-side trace part is grounded, and another end is connected to the first switch chip.

12. The RF module of claim 11, wherein the secondary-side trace part comprises a first secondary-side trace and a second secondary-side trace;
the first secondary-side trace surrounds the periphery of the capacitor and is positioned in a surrounding area defined by the primary-side trace part, and the second secondary-side trace surrounds the periphery of the primary-side trace part; and
a first end of the first secondary-side trace is grounded, and a second end of the first secondary-side trace is electrically connected with a first end of the second secondary-side trace;
and a second end of the second secondary-side trace is connected to the first switch chip.

13. The RF module of claim 7, further comprising a control chip arranged on the substrate; and
the control chip is positioned between the first RF chip and the second RF chip and connected to the first RF chip, the first switch chip, the second RF chip and the second switch chip.

14. The RF module of claim 7, further comprising a third matching circuit arranged in the second layout area; the third matching circuit is positioned between the second RF chip and the second switch chip and connected to the third power amplifier and the second switch chip respectively.

15. The RF module of claim 1, wherein the first power amplifier is a single-ended amplifier circuit, and the second power amplifier and the third power amplifier are differential amplifier circuits.

16. The RF module of claim 1, wherein the first power amplifier and the second power amplifier are both two-stage amplifier circuits, and the first power amplifier comprises a first power supply end and a second power supply end; the second power amplifier comprises a third power supply end and a fourth power supply end; and
the substrate is also provided with a first power supply port and a second power supply port, the first power supply port is connected with the first power supply end and the third power supply end, the second power supply port is connected to the second power supply end and the fourth power supply end.

17. The RF module of claim 16, wherein the third power amplifier is a two-stage amplifier circuit, and the third power amplifier comprises a fifth power supply end and a sixth power supply end; and
the substrate is also provided with a third power supply port, the third power supply port is connected to the fifth power supply end and the sixth power supply end.

18. An RF module, comprising:
a substrate, the substrate is provided with a signal input port and a signal output port, the signal input port comprises a first signal input port, a second signal input port and a third signal input port; a distance between the first signal input port and the second signal input port is smaller than that between the first signal input port and the third signal input port; the first signal input port is configured to input RF signals of a first frequency band, the second signal input port is configured to input RF signals of a second frequency band, and the third signal input port is configured to input RF signals of a third frequency band, and a frequency of the first frequency band is smaller than that of the second frequency band, and a frequency of the second frequency band is smaller than that of the third frequency band;
the signal output port comprises a first signal output port, a second signal output port and a third signal output port; a distance between the first signal output port and the second signal output port is smaller than that between the first signal output port and the third signal output port;
a first RF chip, the first RF chip is arranged on the substrate and connected with the first signal input port and the second signal input port;
a second RF chip, the second RF chip is arranged on the substrate and connected with the third signal input port;
a first switch chip, the first switch chip is arranged on the substrate and connected with the first RF chip, the first signal output port and the second signal output port; and
a second switch chip, the second switch chip is arranged on the substrate and connected with the second RF chip and the third signal output port.

19. The RF module of claim 18, wherein the first RF chip comprises a first power amplifier and a second power amplifier, the first power amplifier is connected with the first signal input port and configured to receive an input signal of the first signal input port, and the second power amplifier is connected with the second signal input port and configured to receive an input signal of the second signal input port;
the second RF chip comprises a third power amplifier, the third power amplifier is connected to the third signal input port and configured to receive an input signal of the third signal input port; and
a distance between the first RF chip and the first switch chip is smaller than that between the first RF chip and the second switch chip.

20. The RF module of claim 19, wherein a distance between the first signal input port and the first RF chip is smaller than that between the first signal input port and the second RF chip; and
a distance between the first signal output port and the first switch chip is smaller than that between the first signal output port and the second switch chip.
